(19) United States
(12) Patent Application Publication
(10) Pub. No.: US 2024/0066554 A1
(43) Pub. Date: Feb. 29, 2024

(54) TRANSDUCER AND METHOD OF MANUFACTURE

(71) Applicant: IONIX ADVANCED TECHNOLOGIES LTD, Huddersfield (GB)

(72) Inventors: Timothy James STEVENSON, Leeds (GB); Chuangnan WANG, Huddersfield (GB)

(21) Appl. No.: 18/253,906

(22) PCT Filed: Nov. 30, 2021
(86) PCT No.: PCT/GB2021/053115

§ 371 Date: May 22, 2023

(30) Foreign Application Priority Data
Dec. 2, 2020 (GB) 2019016.1

(51) Int. Cl. B06B 1/06; H10N 30/088

(52) U.S. Cl. CPC B06B 1/0681; H10N 30/088

(57) ABSTRACT

A method of manufacturing an array transducer arrangement, an array transducer arrangement for use in a high temperature environment, a method of manufacturing an array transducer arrangement for use in a high temperature environment, apparatus for selectively emitting ultrasonic waves in a high temperature environment, a method of producing a porous backing layer for a high temperature array transducer arrangement, and a backing layer for an array transducer arrangement are disclosed. The method of manufacturing an array transducer arrangement comprises: providing a piezoelectric layer; arranging a backing layer on a first face of the piezoelectric layer; and cutting a plurality of primary kerfs through the piezoelectric layer and into the backing layer to provide a plurality of piezoelectric elements; whereby the primary kerfs define a pitch of the plurality of piezoelectric elements.

### TECHNICAL FIELD

The present invention relates to an array transducer arrangement, and associated methods of manufacturing the composite, suitable for use in a high temperature application or environment. In particular, but not exclusively, the present invention relates to an array transducer arrangement that includes kerfs cut through a piezoelectric layer arranged on a backing layer interspaced with an electrode layer. The kerfs extend though the electrode layer and into the backing layer and provide electrically isolated piezoelectric elements which are separated by a surrounding medium suitable for high temperature application. Optionally the backing layer may include a porous region and may exhibit performance characteristics (such as acoustic impedance and/or thermal expansion) that varies across its thickness.

### BACKGROUND

Ultrasonic transducers are used in a variety of applications to perform, for example, fluid flow measurements, non-destructive testing, medical ultrasound testing, vibration control monitoring, diesel fuel injection and ultrasonic cleaning. A number of these applications require the transducers to operate in high temperature environments.

Ultrasonic array transducers conventionally include an ordered series or arrangement of many elements (an array) of a piezoelectric material, usually a lead zirconate titanate (PZT) ceramic, separated by a matrix medium, usually epoxy to make a composite thereof, housed in a polymer or metallic casing and assembled with epoxies, mechanical fixings, electronic components and soldered connections. These multi-element array assemblies can be used where each element is used as eletromechanical transducer elements individually or in multiple groups, as in the example of phased array ultrasonic testing (PAUT), or as a single group making use of the benefits of a composite transducer. Conventionally, the temperature of operation of these multi-element arrays is limited by several factors. In fact, conventional ultrasonic array transducers are typically limited to use below around 80° C.

For example, if the piezoelectric material is heated above its Curie temperature, the material can become depolarized causing the transducer to fail. At elevated temperature, the acoustic insulation between the array elements, usually, in conventional transducers, an epoxy resin or other polymeric material, can deform, delaminate or fail, causing distortion of the closely controlled pitch of a piezoelectric element utilised in a transducer, causing element failure or an unacceptable increase in cross-talk (inter-element noise).

Furthermore, the auxiliary components of the transducer such as, for example, the backing materials, housings and polymer fillers are also prone to failure, or to specification drift and displacement, when they are exposed to elevated temperatures. For example, increasing the temperature causes a dramatic decrease in the speed of sound, and subsequently acoustic impedance, which affects the sensor's sensitivity, frequency, bandwidth and acoustic transmission efficiency.

Certain high temperature ultrasonic transducers have been suggested which work by shielding critical internal components from excessive heat. This might be achieved by either cooling (by liquid or gas), through the addition of a thermal buffer or wedge (to distance the piezoelectric array from the source of heat), or by limiting the thermal exposure time (duty cycling). However, such methods would require the use of complex, oversized or inefficient external features in order to prevent the transducers from overheating, which restricts their use in many applications. Calibration would also be extremely complex and introduce substantial errors to obtained measurements, for example, due to the presence of significant thermal gradients.

Even where high temperature piezoelectric materials are used, the bonds which must be formed between a piezoelectric element and the other components of the transducer, such as the backing and/or the wear plate, are exposed to high temperatures such that the transducer cannot operate effectively at high temperatures for prolonged periods of time, further consideration and limiting any potential industrial application. In particular, the acoustic coupling between the transducer components is known to reduce significantly over time as the bonding between transducer components deteriorates due to high temperature degradation.

Multiple transducer elements can be arranged in a desired configuration, such as in matrix-like configuration, to provide an array of transducers. Transducer arrays are able to emit multiple pulses of sound via the transducer elements, and obtain multiple measurements based on reflections of the sound pulses along a region of a material to be measured. Individual transducer elements of a transducer array can be configured to emit and receive pulses of sound at different instances in time such as in phased array transducers. Applications of transducer arrays include, but are not limited to, medical imaging, industrial non-destructive testing, vehicle sensors and the like.

Arrays of transducers are known and these typically employ a piezo-composite configuration, where an epoxy material matrix exists between each of the piezoelectric regions or elements. This ultimately limits the operating temperature through either failure or excessive drift in ultrasonic properties or physical displacement which causes error in the composite performance, or focal laws which generate and/or govern a typical phased array ultrasonic transducer (PAUT), total focusing method (TFM), or full matrix capture (FMC) measurement.

Piezo-composite materials are used to increase the piezoelectric electro-mechanical coupling, sensitivity and ultrasonic (frequency) bandwidth of the transducer. This is helpful to achieve a short pulse length for each piezoelectric element that can be easily discerned and treated in the relevant focal law mathematics to produce faithful representations of the acoustic sound paths with accurate and precise times-of-flight. Acoustic backings are used to further increase the bandwidth or reduce the pulse length. Both the piezoelectric composite and backings are sensitive to changes in acoustic impedance which determines how the ultrasonic pulses are generated. Variation in temperatures can easily mismatch the impedance between the piezoelectric elements through the polymer matrix, or of the backing material causing crosstalk or ‘ringing’ and extended pulse lengths respectively which appear as noise in the final measurement.

Conventional piezoelectric arrays are currently available for use at temperature up to approximately 80° C., above which the array at least falls outside of acceptable tolerances, or fails irreversibly. Such prior art arrays are commonly fabricated using the ‘dice and fill’ method which involves encasing a matrix of piezoelectric material in epoxy or a similar such substance to form a piezoelectric composite. Arrays produced by such manufacturing techniques are inherently not suitable for use in high temperature environments. For example, when a piezoelectric ceramic is subjected to a high temperature it sometimes will exhibit a change in shape which may be opposed by the surrounding epoxy. Similarly, the epoxy itself may exhibit physical change, for example thermal expansion, resulting in stresses, misalignment and similar problems within a piezoelectric array. Given the precise and sensitive nature of some piezoelectric transducer devices, mechanical and chemical issues associated with high temperature use of conventional transducer arrangements may result in failure and/or the distortion, drift, and high noise-to-signal ratio of obtained measurements.

A typical specification for a conventional ultrasonic phased array transducer for industrial applications is shown in the table below;

| Parameter | Value | |
|---|---|---|
| Centre frequency (f) | 5 | MHz |
| # of elements (n) | 16, 32 or 64 | |
| Pitch (p) | ≤0.6 | mm |
| Passive length (W) | ≥10 | mm |
| Pulse length | <0.6 | μs |

Conventional linear arrays, the most common for industrial applications, follow some common design rules and characteristic features. The frequency of operation is typically 1 to 20 MHz. The active aperture (A) is the total probe active length given by A=n.e+g·(n−1). The passive aperture or elevation (W) is the element length or probe width and is determined by the probe frequency and focal depth range. The pitch determines the beam steerability and beam characteristics, and as a general rule p<0.67λ. A practical value of the element width (e) is determined as e<λ/2 for a given frequency or wavelength (λ). It will be appreciated that the pitch of a piezoelectric element is given by the sum of the width of the element and the distance between the element and a neighboring element. The kerf (g) is the gap between elements.

The individual element centre frequencies, sensitivity and bandwidths (related by 1/pulse length) are required to be within a tight tolerance to give uniform performance, that is, the performance of each element must be similar. The higher the frequency the better resolution in the measurement due to the reduced cycle time and wavelength, but at the expense of penetration into the body under test; attenuation increases with increasing frequency. The array is often manufactured to have a pulse which is relatively short, ideally 1-1.5 wave cycles in length to achieve good measurement accuracy and sensitivity.

Such a prior art assembly has limited capability for high temperature use. At high temperatures the epoxy will denature. At intermediate temperatures (>80° C.), due to the significant thermal expansion coefficient miss-match between the piezoelectric ceramic and the epoxy, bowing and drift in ultrasonic performance may be observed. It is also noted that with increasing temperature of the component under test, often metal in construction, that the acoustic attenuation will increase, requiring high sensitivity, and potentially lower frequency operation (3-5 MHz, from 5-7 MHz at ambient) to reduce scatter and increase signal to noise—lower frequencies suffer lower attenuation.

Prior attempts for high temperature array transducers for PAUT are available in the literature, that have incorporated high-temperature piezoelectric materials, normally based on single crystals such as quartz, lithium niobate and gallium orthophosphate which exhibit high curie temperatures, but suffer from degradation, very low piezoelectric activity constants (orders of magnitude lower than PZT), which in turn produces low sensitivity transducers, and high quality factors which cause ringing and extended pulse lengths beyond an acceptable limit for most applications.

Thin-film based piezoelectric materials have also been tested in array configurations but, due to their inherent low thicknesses, have higher frequencies and lower activity constants thereby leading to lower signal to noise, and requiring much larger operating voltages respectively, than are acceptable for most industrial non-destructive testing applications.

Acoustic laws known to those skilled in the art propose that the ideal configuration for a 5 MHz array result in extremely fragile features and low tolerance to dimensional error. In conventional ambient temperature arrays, the gaps between each element are filled with epoxy providing mechanical strength and robustness. As discussed above, epoxy and other similar filling substances are not suitable for use in high temperature arrays.

It is an aim of the present invention to at least partly mitigate one or more of the above-mentioned problems.

It is an aim of certain embodiments of the present invention to provide an array transducer arrangement for high temperature use.

It is an aim of certain embodiments of the present invention to provide an array transducer arrangement for use above 80 degrees Celsius, for a prolonged period of time.

It is an aim of certain embodiments of the present invention to provide a bonding layer between a piezoelectric layer and a backing layer able to withstand high temperature use for a prolonged period of time.

It is an aim of certain embodiments of the present invention to provide a graded backing layer including a dense region proximate to a piezoelectric layer with an acoustic impedance that substantially matches the acoustic impedance of the piezoelectric layer to minimize sound reflection and a porous region distal to the piezoelectric layer to scatter and/or absorb incident sound.

It is an aim of certain embodiments of the present invention to provide a plurality of piezoelectric transducer elements in an array arrangement in which no epoxy or other filler material is utilised.

It is an aim of certain embodiments of the present invention to provide a method of providing piezoelectric elements by providing kerfs through a piezoelectric layer and into a backing layer.

It is an aim of certain embodiments of the present invention to provide a manufacturing technique suitable for production of multiple piezoelectric elements from a fragile piezoelectric ceramic without the need for epoxy reinforcement.

### STATEMENTS OF INVENTION

According to a first aspect of the present invention there is provided a method of manufacturing an array transducer arrangement for use in across a wide temperature range, including high temperature environments above 80° C., comprising: providing a piezoelectric layer (where Z=20-35 MRayls), providing a backing layer with substantially the same acoustic impedance as the piezoelectric layer across the temperature range at the interface with the piezoelectric layer, and substantially the same coefficient of thermal expansion (a mismatch of no more than +/−7 ppm/K); arranging the backing layer on a first face of the piezoelectric layer; and cutting a plurality of primary kerfs through the piezoelectric layer and into the backing layer, to provide a plurality of piezoelectric elements; whereby the primary kerfs define a pitch of the plurality of piezoelectric elements; cutting a plurality of secondary kerfs into piezoelectric layer (from 0 to 100% through) to tailor the acoustic properties for the given application.

Aptly the backing layer comprises at least one region which is porous.

Aptly the backing layer comprises at least one region which is relatively dense.

Aptly the backing layer comprises at least one region having an acoustic impedance substantially similar to the acoustic impedance of the piezoelectric layer, and remains substantially similar as a function of temperature.

Aptly the method further comprises providing an electrode layer on the first face of the piezoelectric layer such that the electrode layer is locatable between the piezoelectric layer and the backing layer, whereby the primary kerfs extend through the electrode layer.

Aptly the method further comprises providing an electrode layer on a further face of the piezoelectric layer, whereby the primary kerfs extend through the electrode layer.

Aptly the method further comprises providing an electrode layer on a second face the piezoelectric layer and the backing layer and/or on top of the piezoelectric layer, whereby the primary kerfs extend through the electrode layer.

Aptly the method further comprises cutting a plurality of secondary kerfs into the first face or the second face or a further face of the piezoelectric layer, the further kerfs extending through a portion of a thickness of the piezoelectric layer.

Aptly the secondary kerfs provide a plurality of pillar-like sub-elements.

Aptly the method further comprises providing the piezoelectric layer from Ionix HPZ-580 material, but alternatively PZT, or any other piezoelectric material.

Aptly the method further comprises providing the backing layer from Ionix HPZ-580 material.

Other types of backings may be used, so long as the thermal expansion conforms to +/7 ppm/K and the acoustic impedance, Z, remains substantially matched.

Aptly the backing layer comprises Ionix HPZ-580 material in a depoled state.

Aptly the method further comprises providing a glassy frit bonding layer between the piezoelectric layer and the backing layer.

Aptly the piezoelectric elements are elongate pillar-like structures arranged perpendicularly to the major axis of the piezoelectric layer.

Aptly the piezoelectric elements include a plurality of elongate pillar-like structures which are connected along a distal end of each pillar-like structure.

Aptly the piezoelectric elements are box-like.

Aptly the piezoelectric elements have a maximum length parallel to the major axis of the piezoelectric layer and a minimum length perpendicular to the piezoelectric layer.

According to a second aspect of the present invention there is provided an array transducer arrangement for use in a high temperature environment, comprising: at least one piezoelectric layer; at least one backing layer arranged on a first face of the piezoelectric layer; and a plurality of primary kerfs extending through the piezoelectric layer and into the backing layer to provide a plurality of piezoelectric elements; wherein the primary kerfs define a pitch of the plurality of piezoelectric elements.

Aptly the plurality of piezoelectric elements form an array.

Aptly the piezoelectric layer comprises Ionix HPZ-580.

Aptly the backing layer comprises Ionix HPZ-580, optionally in a depoled state.

Aptly the backing layer includes at least one dense region proximate to the piezoelectric layer.

Aptly the backing layer includes at least one porous material distal to the piezoelectric layer.

Aptly the porosity of the backing layer is graduated/graded along its length, height or width.

Aptly the array transducer arrangement further comprises a plurality of secondary kerfs are cut into a further surface of the piezoelectric layer and extend though a portion of a thickness of the piezoelectric layer.

Aptly the secondary kerfs define pillar-like sub-elements.

Aptly the piezoelectric elements include a plurality of sub-elements.

Aptly the piezoelectric elements are box-like.

Aptly the piezoelectric elements are pillar like.

Aptly the piezoelectric array transducer arrangement is a 2D arrangement with primary kerfs extending along one axis in a plane provided by the further surface of the piezoelectric layer.

Aptly the piezoelectric array transducer arrangement is a 3D arrangement with primary kerfs extending along two axes in a plane provided by the further surface of the piezoelectric layer.

Aptly the array transducer arrangement further comprises a bonding layer between the piezoelectric layer and the backing layer.

Aptly the bonding layer comprises a frit layer.

Aptly the bonding layer can survive thermal mismatch strains up to +/−7 ppm/K, over the temperature range.

Aptly the array transducer arrangement further comprises at least one electrode layer.

Aptly the electrode layer is located proximate to the first face of the piezoelectric layer.

Aptly the electrode layer is located proximate to the further face of the piezoelectric layer.

Aptly the primary kerfs extend through the electrode layer and electrically isolate the piezoelectric elements.

According to a third aspect of the present invention there is provided a method of manufacturing an array transducer arrangement for use in a high temperature environment, comprising: providing an electrode layer, providing a piezoelectric layer on a first face of the electrode layer using additive manufacturing techniques.

Aptly the method further comprises providing a backing layer on a further face of the electrode layer.

Aptly the method further comprises curing the piezoelectric layer.

Aptly the additive manufacturing techniques include 3D printing.

Aptly the method further comprises providing a plurality of primary kerfs though the piezoelectric layer, through the electrode layer and into the backing layer to define a plurality of piezoelectric elements of a particular pitch.

Aptly the method further comprises providing a plurality of secondary kerfs into the piezoelectric layer, the secondary kerfs extending partially through the piezoelectric layer to provide a plurality of sub-elements.

Aptly the piezoelectric layer comprises Ionix HPZ-580.

Aptly the backing layer comprises Ionix HPZ-580, optionally in a depoled state.

According to a fourth aspect of the present invention there is provided an array transducer arrangement for use in a high temperature environment, comprising: at least one piezoelectric layer; at least one electrode layer; and at least one backing layer; wherein the at least one backing layer includes a first region proximate to the piezoelectric layer and a further region distal to the piezoelectric layer, the further region including a plurality of pores.

Aptly the further region is porous.

Aptly the first region has an acoustic impedance being substantially similar to the acoustic impedance of the piezoelectric layer.

Aptly the piezoelectric layer comprises a region of Ionix HPZ-580 material.

Aptly the backing layer comprises a region of Ionix HPZ-580 material, optionally in a depoled state.

Aptly the array transducer arrangement further comprises a plurality of primary kerfs though the piezoelectric layer, through the electrode layer, through and into the backing layer to define a plurality of piezoelectric elements of a particular pitch.

Aptly the array transducer arrangement further comprises a plurality of secondary kerfs into the piezoelectric layer, the secondary kerfs extending partially through the piezoelectric layer to provide a plurality of sub-elements.

According to a fifth aspect of the present invention there is provided a method of producing a porous backing layer for a high temperature array transducer arrangement, comprising: providing a sinterable powder into a pellet forming die; providing a mixture of sinterable powder and a pore former on top of the sinterable powder; pressing the mixture together to form an unsintered block; removing the pore former to provide cavities; and sintering the unsintered block.

Aptly the backing layer comprises Ionix HPZ-580, optionally in a depoled state.

Aptly the method further comprises providing a piezoelectric layer to/over at least one face of the backing layer.

Aptly pore former is removed by burning and/or ashing.

According to a sixth aspect of the present invention there is provided a backing layer for an array transducer arrangement, comprising: a first region; a further region; wherein the first region is relatively dense, the further region being relatively porous, the further region including pores to scatter/absorb sound.

Aptly the backing layer comprises Ionix HPZ-580, optionally in a depoled state.

According to a seventh aspect of the invention there is provided an array transducer arrangement for use in a high temperature environment or on a component under test with a high surface temperature, the transducer arrangement comprising: many piezoelectric elements comprising a piezoelectric material, the piezoelectric material being arranged for generating and receiving acoustic energy. A backing material to absorb and/or scatter, rearward facing acoustic energy, with an acoustic impedance substantially similar to that of the piezoelectric through the operating temperature range. A means of bonding the piezoelectric elements to the backing material, in such a way the array elements are able to withstand high temperature and maintain acoustic coupling. This bond may be either electrically conductive, or electrically resistive. A means of addressing each element electrically, and individually. This connection may be made at the interface to the backing (the rear) or on the front face. There may be a common earth, or multiple common earths on the opposite side of the elements to the actuation/sensing electrical elements.

Aptly there may be a wear plate on the front face of the piezoelectric array for protecting the piezoelectric elements from the article which is under inspection from interface wear.

Aptly there may be a metal housing which contains the array assembly.

Aptly there may be other electrically insulating or electrically isolating materials included within the assembly.

Aptly there may be a harness and/or strain relief to connect the array to an ultrasonic controller.

Aptly the wear plate may be in the form of a wedge to cause refraction of the ultrasonic beam to produce longitudinal and shear mode waves according to Snells law.

Aptly the piezoelectric element may have a Curie temperature of at least 350° C. making it a high temperature transducer of ultrasonic signals.

The piezoelectric material may have a Curie temperature of at least 400 or 500° C. The piezoelectric element may exhibit a Curie temperature which is at least any one of the following temperatures: at least 450° C., at least 550° C., at least 600° C., at least 650° C., at least 675° C. and at least 700° C.

The piezoelectric material may comprise a ceramic having a solid solution of formula: x(BiₐK₁₋ₐ)TiO₃-yBiFeO₃-zPbTiO₃; wherein 0.4≤a≤0.6; 0<x<1; 0<y<1; 0<z≤0.5; and x+y+z=1; wherein the ceramic is substantially free of non-perovskite phases, other than porosity.

The array may be placed on a hot body, to send and receive ultrasonic energy, to detect for example a flaw. Aptly the temperature of the hot body may be >80° C. Aptly the temperature of the hot body is >200° C. Aptly the temperature of the hot body is >350° C. Aptly the temperature of the hot body may is >500° C. Aptly the body may be <0° C., <100° C., <200° C.

The array may be designed to work at a range of ultrasonic frequencies. Aptly the range of frequencies is between 1 and 20 MHz, optionally between 2 and 12 MHz.

Optionally the thickness of the bonding layer between the piezoelectric elements and the backing, and the front face is around <¼λ to help avoid interference with a measurement.

Aptly the acoustic impedance of the backing can be substantially matched to that of the piezoelectric materials. The backing may be formed from the same material as the piezoelectric. Optionally the backing material may contain internal porosity, and be unpoled. The porosity may be <30 vol %, and may be <20 vol %. The porosity may be >5 vol %, and may be >10% vol.

The backing may be <10% porosity, <5% or essentially no porosity. The backing may optionally be a composite, a ceramic, a metal or a high temperature polymer.

Aptly the porosity may be highly ordered. Optionally, the porosity is scattered and forms no set pattern.

Aptly the porosity of the backing may be graded. That is, the face of the backing which is attached to the active piezoelectric elements may have no, or lower, porosity than the region of the backing material which is furthermost from the piezoelectric material/layer. In this manner, a strong bond and high acoustic energy transmission interface, may be formed and the acoustic impedance is substantially well matched.

Aptly in the case of a graded backing, a face of the backing which attaches to the piezo may have <10% porosity. Optionally the porosity is <5% or <2% or zero porosity. The porosity of the face of the backing which attaches to the piezo may optionally have the same level of porosity as the active piezo element. The thickness of this low porosity region may be <10 mm or <5 mm. Aptly the thickness is <3 mm or <2 mm or <1 mm. The thickness of this low porosity region may be >λ/4. It may be >0.1, 0.2, 0.3, 0.5, or 1.0 mm.

Optionally the thickness of the backing is sufficient such as to scatter and absorb any rearward acoustic energy such that a reflection from the rearward face of the backing does not interfere with the measurement.

Aptly the thickness of the low porosity region of the backing may be <50% of the total thickness of the backing. Aptly the thickness is <40%, or optionally <30%. The thickness of the low porosity region of the backing may optionally be >1%, >2%, >5%, >10%, >20%, >30%, >40% or >50% of the total thickness of the backing material.

Optionally the graded backing may be made by bonding a dense material to a porous material, both materials of which have a similar acoustic impedance in dense form.

Optionally the graded backing may be made by the steps of:
(a) Loading a x % of a sinterable powder into a pellet forming die.
(b) Loading 100−x % of a mixture of sinterable powder and a pore former such as polymer beads on top of the sinterable powder.
(c) Pressing the mixture together to make a green (unsintered ceramic) block.
(d) Removing the pore former used by burning out the powder, in order to ash the pore former. In such a process, the cavities remain.
(e) Sintering the green body.
(f) The resultant body has one region which is significantly more dense than the other.
(g) Machining at least one face to marry to the piezoelectric array elements.

The bonding layer between the active piezo element and the backing and/or the wear face may have an acoustic impedance of between 5 MRayl and 50 MRayl. The bonding layer may further comprise a porosity of less than 10%. The bonding layer may be suitably configured to provide an efficient medium through which ultrasonic signals may be transmitted. The bonding layer may have an acoustic impedance which is matched, or substantially matched, to both the piezoelectric element and the backing or the wear face.

Aptly The bonding layer may be formed from a ceramic containing melted or sintered glass powder, such as a FRIT. The bonding layer may be formed from a high temperature solder.

The bond layer may be an active braze. The bond layer maybe epoxy, or substantially epoxy with ceramic fillers. The bonding layer may be electrically conductive, or electrically insulating.

Aptly the bonding layer may exhibit substantially the same thermal expansion coefficient as the piezoelectric and backing layer, within +/−7 ppm/K, over the temperature range of interest.

According to an eighth aspect of the invention, there is provided a method of manufacturing a transducer arrangement via the steps of:

1. Forming a Bulk Ceramic Array
A poled and electroded piezoelectric ceramic is formed at the desired thickness and dimensions. As an example, this piezoelectric ceramic is 10×10 mm in area, with one dimension as the elevation (W), 5 MHz thick, but it is appreciated this would be application dependent. The piezoelectric ceramic may be poled.
A graded ceramic backing is formed of the desired dimension. As an example, this backing is 10×11×10 mm thick, but it is appreciated this would substantially match the piezoceramic dimensions or be application dependent.
One or more layers of conductive glass frit are applied to the piezoelectric element and/or the front face of the ceramic backing, but is appreciated that an alternative bond as described above could be used depending on the operating temperature and application. Regions may optionally be applied to the ceramic backing to assist with electric connectivity, such as conductive tracks or dielectric layers
A bond is formed between the piezoelectric element and the backing, using temperature, or force and temperature, to the desired thickness. This bonding process (temperature and stress) may be below the Curie point/Curie stress for the ceramic, such that repolarization of the piezo is not necessary. It may be above or close to the Curie point, such that repolarization is necessary.
Kerfs are cut into the piezoelectric ceramic plate to make an array of pillars. It is appreciated the depth and width of the kerf is dependent on the application frequency and acoustic performance characteristics required, such as bandwidth. The primary kerfs may be cut such that their pitch is that of the final required element pitch, or secondary kerf cuts such as to produce sub-diced pillars to control acoustic performance.
Optionally, no filler is used between the elements of the array. This removes the need for an organic filler. Air or vacuum may be effective as a filler. Any continuous inorganic filler (with inevitably a higher acoustic impedance than a polymer) may lead to some cross talk between the elements.
Electrical connections are made to the array pillars, with electrical connections arranged such that the pillars are grouped into the number of elements required.
Optionally, for an n element array, n+2 elements are formed, where the 2 outermost elements are connected to ground or disconnected from the ultrasonic controller acting as sacrificial elements to maintain constant damping and acoustic properties across the remaining n elements.
Optionally, a wear face or wedge is bonded on to the piezoelectric layer. One or more layers of conductive lead free or leaded solder is applied to the piezoelectric element and/or the front face of the wear plate or wedge, but is appreciated that an alternative bond as described above could be used depending on the operating temperature and application. The conductive layer forms an electrical ground plane to the individual elements.
Optionally a bond is formed between the piezoelectric element and the wear plate or wedge, using temperature, or force and temperature, to the desired thickness. This bonding process (temperature and stress) may be below the Curie point/Curie stress for the ceramic, such that repolarization of the piezo is not necessary.

2. Forming a Ceramic Coating.

Rather than using a traditional bulk ceramic (sintered, ground, electrode, poled, cut into arrays) certain embodiments of the present invention manufacture using a coating directly onto an electrode backing. Individual elements can either be formed in the green state, or in the case of a deposition technique, the elements may be formed by masking. The coating can optionally be deposited by additive manufacturing such that the material is deposited only in areas required to form elements, controlled by a computer. Optionally, the elements may be formed in the green, unfired, state.

Such a coating method has the following advantages
Ease of manufacture.
Excellent acoustic coupling to the backing.
Ability to readily manufacture curved or focused arrays.
Ability to tailor the materials properties, such as acoustic loss, thermal expansion, etc.

Examples of means by which to coat a backing with a piezoelectric ceramic material include
Manufacture of a 0-3 composite (a mixture of ceramic and filler).
Evaporation, ALD, other plasma technique, laser sputtering.
Sol-gel.
Powder deposition.

According to a ninth aspect of the present invention there is provided a method of manufacturing an array transducer arrangement for use in a high temperature environment, comprising: providing a region of piezoelectric material, providing a backing layer over a first surface of said a piezoelectric region; and cutting a plurality of spaced apart primary slits through said a piezoelectric region and into the backing layer; wherein respective portions of the piezoelectric region between adjacent slits each provide respective piezoelectric elements.

Aptly a pitch of the piezoelectric elements is determined by a spacing distance between the primary slits.

Aptly a pitch of the piezoelectric elements is provided by a spacing distance between the primary slits and the width of at least one slit.

Aptly the slits are kerfs.

Aptly the portions of the piezoelectric region have an aspect ratio that is plate like or bar like.

Aptly a first layer of electrode material is disposed between said a region of piezoelectric material and the backing layer prior to cutting said a plurality of slits and the method includes cutting through said a first layer when the primary slits are cut.

According to a tenth aspect of the present invention there is provided apparatus for selectively emitting ultrasonic waves in a high temperature environment, comprising: at least one region of a piezoelectric material; at least one backing layer arranged over a first surface of said a region of piezoelectric material; and a plurality of primary slits extending through said a region of piezoelectric material and into the backing layer; wherein respective portions of the piezoelectric region between adjacent slits each provide respective piezoelectric elements.

Aptly a pitch of the piezoelectric elements is determined by a spacing distance between the primary slits.

Aptly a pitch of the piezoelectric elements is provided by a spacing distance between the primary slits and the width of at least one slit.

According to an eleventh aspect of the present invention there is provided a method of manufacturing an array transducer arrangement for use in a high temperature environment, comprising: providing a piezoelectric layer, providing a backing layer; arranging the backing layer on a first face of the piezoelectric layer; and cutting a plurality of primary kerfs through the piezoelectric layer and into the backing layer, to provide a plurality of piezoelectric elements; whereby the primary kerfs define a pitch of the plurality of piezoelectric elements.

Aptly the backing layer comprises at least one region which is porous.

Aptly the backing layer comprises at least one region which is relatively dense.

Aptly the backing layer comprises at least one region having an acoustic impedance substantially similar to the acoustic impedance of the piezoelectric layer.

Aptly the method further comprises providing an electrode layer on the first face of the piezoelectric layer such that the electrode layer is locatable between the piezoelectric layer and the backing layer, whereby the primary kerfs extend through the electrode layer.

Aptly the method further comprises providing an electrode layer on a further face of the piezoelectric layer, whereby the primary kerfs extend through the electrode layer.

Aptly the method further comprises providing an electrode layer on a second face the piezoelectric layer and the backing layer and/or on top of the piezoelectric layer, whereby the primary kerfs extend through the electrode layer.

Aptly the method further comprises cutting a plurality of secondary kerfs into the first face or the second face or a further face of the piezoelectric layer, the further kerfs extending through a portion of a thickness of the piezoelectric layer.

Aptly the secondary kerfs provide a plurality of pillar-like sub-elements.

Aptly the method further comprises providing the piezoelectric layer from Ionix HPZ-580 material.

Aptly the method further comprises providing the piezoelectric layer from PZT, or any other piezoelectric material.

Aptly the method further comprises providing the backing layer from Ionix HPZ-580 material.

Aptly the backing layer comprises Ionix HPZ-580 material in a depoled state.

Aptly the thermal expansion of the backing conforms to +/7 ppm/K and the acoustic impedance, Z, remains substantially matched.

Aptly the method further comprises providing a glassy frit bonding layer between the piezoelectric layer and the backing layer.

Aptly the piezoelectric elements are elongate pillar-like structures arranged perpendicularly to the major axis of the piezoelectric layer.

Aptly the piezoelectric elements include a plurality of elongate pillar-like structures which are connected along a distal end of each pillar-like structure.

Aptly the piezoelectric elements are box-like.

Aptly the piezoelectric elements have a maximum length parallel to the major axis of the piezoelectric layer and a minimum length perpendicular to the piezoelectric layer.

Certain embodiments of the present invention describe an array suitable for long durations of use through varying temperatures and at high temperatures. They may be employed for use in applications, for example on-stream, in-service a) crack and corrosion/erosion monitoring and imaging in high-temperature components, b) high-temperature flow measurements and c) weld and bolt/fastener inspections operating at high-temperature.

Certain embodiments of the present invention provide a relatively robust method of manufacturing array transducer arrangements for high temperature application.

Certain embodiments of the present invention provide an array transducer arrangement with for us in high temperature application.

Certain embodiments of the present invention provide a grading backing layer for an array transducer arrangement for use in a high temperature environment including at least one dense region and at least one porous region.

Certain embodiments of the present invention provide a manufacturing technique wherein piezoelectric ceramic is provided directly onto an electrode layer by additive manufacturing.

Certain embodiments of the present invention provide an array transducer arrangement with an advantageous k₃₃/kₜ ratio.

Certain embodiments of the present invention provide a method of manufacturing an array transducer arrangement which eliminates a need for epoxy or filler reinforcement.

Certain embodiments of the present invention provide an array transducer arrangement for prolonged use above 80 degrees.

### BRIEF DESCRIPTION OF THE DRAWINGS

For a better understanding of the invention, and to show how embodiments of the same may be carried into effect, reference will now be made, by way of example only, to the accompanying diagrammatic drawings in which:

FIG. 1 illustrates a manufacturing process for producing an array transducer arrangement;

FIG. 2a illustrates a first array transducer arrangement prior to a primary cutting/kerfing stage;

FIG. 2b illustrates a first array transducer arrangement following a primary cutting/kerfing stage;

FIG. 3a illustrates a second array transducer arrangement prior to primary and secondary cutting/kerfing stages;

FIG. 3b illustrates a second array transducer arrangement following a secondary cutting/kerfing stage and prior to a primary cutting/kerfing stage;

FIG. 3c illustrates a second array transducer arrangement following primary and secondary cutting/kerfing stages;

FIG. 4a illustrates a third array transducer arrangement prior to a primary cutting/kerfing stage;

FIG. 4b illustrates a third array transducer arrangement following a primary cutting/kerfing stage;

FIG. 5 illustrates a graded backing layer for use in a high temperature array transducer arrangement;

FIG. 6 illustrates measurements of the second array transducer arrangement;

FIG. 7 illustrates measurements of the third array transducer arrangement;

FIG. 8a illustrates amplitude against time scans on a carbon steel block using the third array transducer arrangement at 20° C.;

FIG. 8b illustrates aptitude against time scans on a carbon steel block using the third array transducer arrangement at 250° C.; and

FIG. 9 illustrates a steel carbon black scan from an ultrasonic flaw detector using the third array transducer arrangement.

### DETAILED DESCRIPTION

Certain embodiments of the present invention relate to an array transducer arrangement suitable for use in high temperature environments. Certain embodiments of the present invention relate to an array of piezoelectric elements, a bonding layer, a backing material (or acoustic absorber) a front face (or wear face or wedge) and electrical connections.

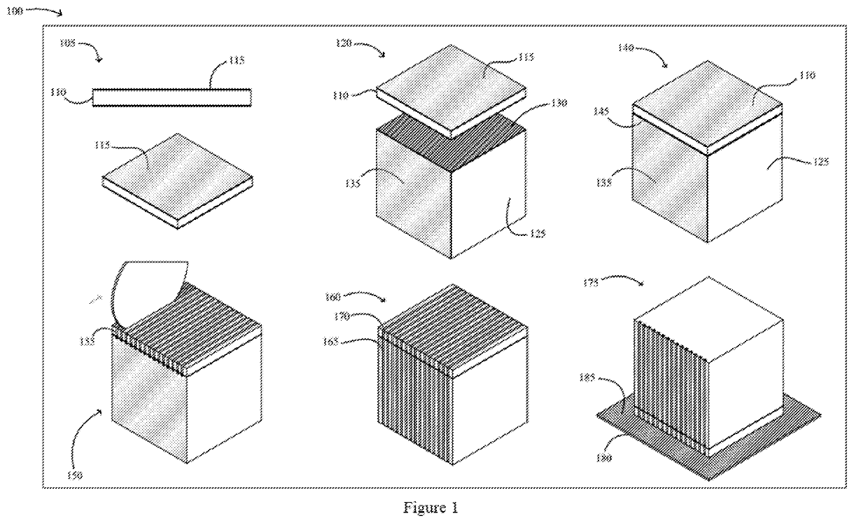

FIG. 1 illustrates helps illustrate a manufacturing process for a piezoelectric transducer array 100 to an example specification shown in the table below.

| Transducer specification | | |
|---|---|---|
| Centre frequency (f) | 4.25 | MHz |
| −6 dB bandwidth | >70% | |
| # of elements (n) | 16 | |
| Pitch (p) | 0.6 | mm |
| Kerf (g) | 0.05 | mm |
| Elevation (W) | 10.0 | mm |

At stage 1 of FIG. 1 105 a region of piezoelectric material 110 (such as a layer) is manufactured, poled and electroded. The piezo layer of FIG. 1 is optionally a piezo electric ceramic. The piezo electric layer optionally includes Ionix HPZ580. The piezo electric layer is produced to have a thickness resonance corresponding to the application centre frequency (f), and geometry incorporating a surface area where one dimension is the elevation (W). A conventional electrode layer 115 is provided over both spaced apart sides/surfaces of the piezoelectric layer. The electrode layers are optionally provided as an ink by screen printing. Optionally, any other suitable method for applying electrodes may be used. Optionally an electrode layer is provided on a single side/surface of the piezoelectric region. The electrode layer is optionally in the order of 3 to 15 μm.

At stage 2 120 of FIG. 1 a backing layer 125 is provided to acoustically damp the piezoelectric crystal and control the bandwidth performance. Optionally a graded porous, or porous backing is manufactured. Optionally the backing is produced from substantially the same material as the material of the piezoelectric region. Optionally at least a portion of the backing layer has an acoustic impedance that is substantially similar to the acoustic impedance of the piezoelectric layer.

A conventional conductive silver frit layer 130 is applied to the piezo 110 and/or the backing 125 and air dried. Optionally, successive layers maybe provided and dried to achieve the desired thickness. The conductive layers are optionally provided as an ink by screen printing. Optionally, conductive silver frit 135 can be extended to the sides of the backing to offer a high-temperature electrical connection to the piezo-backing interface, and air dried.

At stage 3 140 of FIG. 1 the piezoelectric layer and the backing layer are bonded together using heat, or heat and force to achieve desired thickness. In one embodiment, the temperature and force applied is 560° C. and 0.5 MPa for 20 minutes. In one embodiment the bond line thickness is in the range of 10 to 25 microns, and less than 100 μm). Silver frit 135 applied to the backing sides is simultaneously bonded. It will be appreciated that a glassy/frit bonding layer 145 is able to withstand substantially higher temperatures than an epoxy layer. It will also be appreciated that any other suitable conductive frit may be utilized, for example, conductive frits for manufacturing electrical tracks on alumina ceramics. It will further be appreciated that any other method of bonding suitable for high temperatures may be utilised. It will be appreciated that an electrode layer is thus interspaced/interposed between the bonded piezoelectric layer and backing layer.

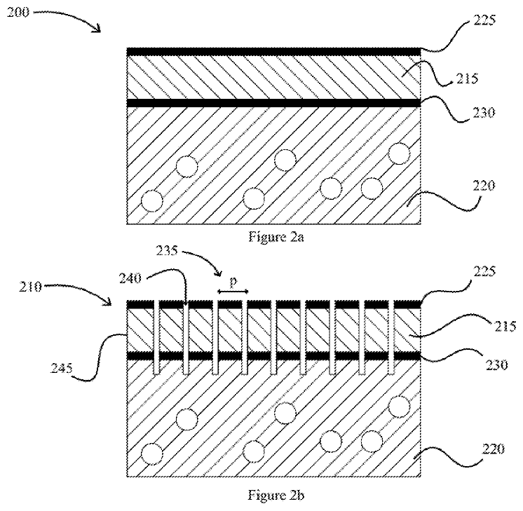

At stage 4 150 of FIG. 1, kerfs or slits 155 are provided into the piezoelectric layer/region. The kerfs are slits. Optionally the kerfs/gaps are provided by sawing or slicing. In one embodiment the saw blade thickness produces the kerf width (g) of 0.05 mm. Primary kerfs/gaps are sawn through the piezoelectric layer and at least partially into the backing. It will be appreciated that these kerfs/gaps extend through both electrode layers. Optionally the slits are spaced apart and substantially parallel with each other. Optionally, n+2 elements are produced by the primary kerfs. Secondary kerfs/slits are optionally provided partially through the piezoelectric layer. The optional secondary kerfs do not extend through the electrode layer interspaced between the piezoelectric layer and the backing layer. Nor do these secondary slits extend into the backing layer. The primary kerf/gaps electrically isolate portions of the piezoelectric layer and thus provide the piezoelectric elements. That is to say that each piezoelectric element is separated by at least one primary kerf/gap The optional secondary kerfs by contrast define the topographical profile of the piezoelectric elements which affects particular properties of the piezoelectric elements such as the coupling coefficient, k. The primary and secondary kerfs/gaps may be provided to obtain any desired piezoelectric element pitch and profile. The kerfs/gaps may also be provided to obtain 2D or 3D array transducer arrangements. Examples of particular arrangements are illustrated in FIGS. 2a to 4b.

At stage 5 160 of FIG. 1, kerfs or slits 165 are provided into the backing, extending past the silver frit layer thickness, which bonds the active piezoelecment to the backing. The kerfs are slits. Optionally the kerfs/gaps are provided by sawing or slicing. The kerf spacing is matched to the primary kerfs 155 through the piezoelectric layer to make each element 170 individually electrically addressable from an adjacent face to where the active piezo element is attached.

At stage 6 175 of FIG. 1, optionally, conventional lead-free or leaded solder 185 is applied to a wear plate or wedge 180. A wear plate (or wedge, or curved surface) 180 and the piezoelectric layer elements are bonded together (heat, temperature and/or force). In one embodiment conventional solder paste is applied to a 0.25 mm thick (or a function of the wavelength for the frequency of array), conventional metallised alumina plate and heated to reflow temperature of 235° C. for 40 seconds. It will be appreciated that a solder layer 185 is able to withstand substantially higher temperatures than an epoxy layer. The solder are optionally provided as a paste by screen printing. It will be appreciated that any other suitable method may be utilised including conventional brazes or conductive silver frit to achieve the same result depending on the application and operating temperature range required. Optionally the wear plate might be a wedge for creating refracted waves. Optionally the wedge and wear plate materials maybe metallised polymers, metallised ceramics or metals depending on the application and component under test material of construction. In one embodiment, conventional micro coaxial cabling terminating at the ultrasonic controller can be joined to the kerfed silver frit layer 165 corresponding to the appropriate elements using conventional solder and soldering techniques. A common connection to ground is made through the conductive layer on the piezo-wear plate interface 185. Optionally an electrical ground is made to each element in the absence of a wear plate or wedge. It will be appreciated that any other suitable method may be utilised including conventional conductive epoxies or wire bonding techniques such as ultrasonic, to achieve the same result depending on the application and operating temperature range required.

FIGS. 2a and 2b illustrate a first transducer array arrangement. The first transducer arrangement is an example of an array manufactured according to relevant design rules to substantially meet relevant acoustic laws. The transducer arrangement is an example of apparatus for selectively emitting ultrasonic waves. FIG. 2a illustrates the first transducer array prior to a kerfing stage 200 in which kerfs/gaps are provided through the piezoelectric layer and into the backing layer. FIG. 2b illustrates the first array transduced following a primary kerfing stage 210. The array transducer illustrated in FIGS. 2a and 2b is manufactured as per the method illustrated in FIG. 1. The first transducer arrangement includes a piezoelectric layer 215 bonded to a backing layer 220. Two electrode layers 225, 230 are provided on an upper surface and a lower surface of the piezoelectric layer 215. It will be understood that an electrode layer 230 is interspaced between the piezoelectric layer and backing layer.

The first array transducer includes a plurality of piezoelectric elements 235. Primary kerfs/gaps 240 are provided through the piezoelectric layer 215 to produce a plurality of elongate pillars or plate like elements, or sub elements, 245 of piezoelectric material. The primary kerfs 240 extend through the piezoelectric layer 215 and into the backing layer 220. It will be appreciated that the primary gaps/kerfs/slits 240 extend through both electrode layers 225, 230. Each pillar 245 is therefore electrically isolated and thus constitutes a piezoelectric element 235. Alternatively, each piezoelectric element is made up of a number of pillars, or sub elements which may be electrically connected using electrodes, cabling, wires and the like. The forming of an air-filled composite serves to improve the bandwidth, and provides a higher performance. Additionally, the air-filled composite does not suffer limitations associated with epoxy deformation and the like and can therefore operate at a higher temperature. In this configuration, the array utilizes the ‘33’ mode coupling coefficient, k₃₃, as the piezoelectric ceramic is less constrained in a direction perpendicular to the poling direction. It is noted that, although these arrays are capable of high temperature use, they have applicability at all temperatures and have similar performance to epoxy based systems at near ambient temperatures. Alternative fluids such as noble gasses or other neutral gasses can optionally be provided between adjacent piezoelectric elements.

The small footprint of each element 235 or pillar 245 is well bonded to the backing layer 220 due to the glass frit bonding method and is robust enough to resist the cutting process in which the primary gaps/kerfs 240 are provided. The arrangement, including the glass frit bonding between the piezoelectric layer and the backing layer, provides support such that the extremely fragile piezoelectric material can withstand the cutting process.

As indicated above, each primary kerf (for the elements 235 and pillar) is made though the piezoelectric layer 215, which optionally is composed of ceramic material, through the bonding layer, and into the backing layer 220. A number of sub-elements or pillars are optionally then electrically joined together to provide piezoelectric elements of the required/desired pitch. The pitch of a piezoelectric element in which three pillars 245 are electrically connected (the electrical connection not being shown in FIG. 2b) is indicated by p in FIG. 2b.

Optionally a number of sub-elements or pillars are joined together electrically to form an array element upon application of appropriate electric connections.

Optionally the backing layer is graded and/or includes pores.

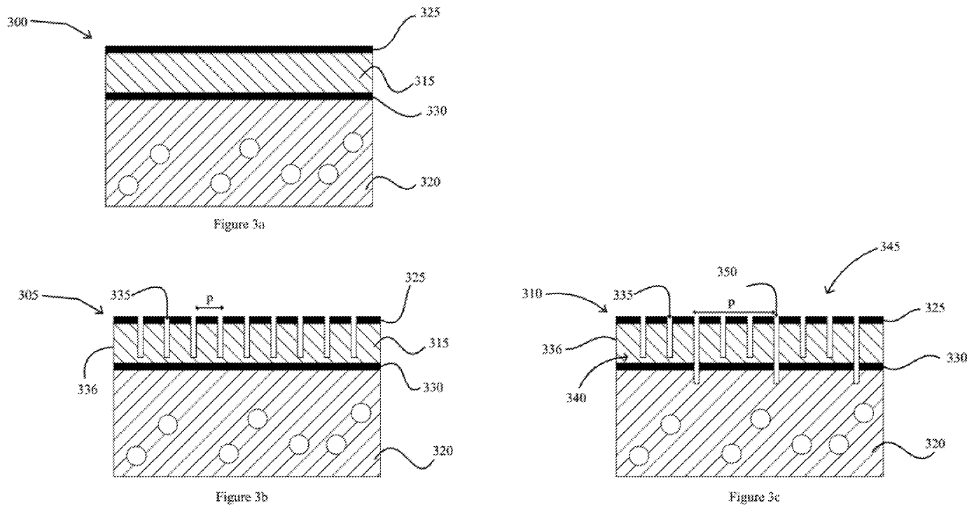

FIGS. 3a, 3b and 3c illustrate a second transducer array arrangement. FIG. 3a illustrates the second transducer array prior to primary and secondary kerfing/cutting stages 300. FIG. 3b illustrates the second array transducer following a secondary kerfing/cutting stage and prior to a primary cutting/kerfing stage 305. FIG. 3c illustrates the second array transducer following primary and secondary kerfing stages 310. The array transducer illustrated in FIGS. 3a, 3b and 3c is manufactured as per the method illustrated in FIG. 1. The second transducer arrangement includes a piezoelectric layer 315 bonded to a backing layer 320. Two electrode layers 325, 330 are provided on an upper surface and a lower surface of the piezoelectric layer 215. It will be understood that an electrode layer 330 is interspaced between the piezoelectric layer and backing layer. Optionally an electrode layer is provided on only one surface of the piezoelectric layer/region.

The second array transducer arrangement provides an alternative in terms of machinability when compared to the first array transducer arrangement illustrated in FIGS. 2a and 2b. In the second array transducer arrangement, two cutting processes are employed. In the initial cutting stage, secondary kerfs 335 are cut into the active piezoelectric ceramic 315, but not all of the way through (typically extending between 70 and 95% of the thickness of the piezoelectric layer, optionally extending between 80 and 90% of the thickness of the piezoelectric layer), such that the bonding area 340 between a piezoelectric element 345 and the backing layer 320 is increased, increasing mechanical strength, reducing flexibility and likelihood of failure. Pillars 336 which are pillar like elements in the sense that their aspect ratio makes them pillar like in height and width but can vary in length (into the page in the figures)) are therefore provided in the region 315 of the piezoelectric layer material The structure of the piezoelectric layer may also be described as being comb-like, each of the vertical pillars being adjoined along one face of the piezoelectric layer.

In the further cutting stage, primary kerfs 350 are cut through the piezoelectric layer and into the backing layer 320. The primary kerfs 350 provide a plurality of piezoelectric elements 345. Each element is electrically separated, by the cutting of the primary kerfs through the ceramic/piezoelectric layer, through at least one electrode layer 325, 330, through the bond layer, and into the backing 320 at the required element pitch. The pitch of a piezoelectric element which includes 3 pillars 336 is denoted by p in FIG. 3c.

The first cutting stage (in which the secondary kerfs are cut) therefore provides the pillars or sub-elements which are a substructure of each piezoelectric element. The further cutting stage (in which the primary kerfs are cut) provides the piezoelectric elements of a desired pitch which can be individually electrically addressable.

The second array transducer arrangement is hybrid mode which provides much more reliable cutting when compared to the first array transducer arrangement illustrated in FIGS. 2a and 2b. When compared with the first array transducer arrangement however, the second array transducer arrangement may exhibit more cross talk through the uncut region of the piezoelectric ceramic. Additionally, there may be less utilization of the advantageous k₃₃ mode of the piezoelectric ceramic in the second array transducer arrangement. The region of the ceramic which is uncut (attached to the bonded region) utilizes the thickness mode (kₜ). In PZT5A (PIC255, PI Ceramic, Germany) a typical PZT suitable for use in an array, k₃₃=0.69, and kₜ=0.47. The coupling coefficient, k, relates directly to bandwidth, hence the higher the k, the higher the performance of the array. k₃₃ is significantly more advantageous that kₜ mode in PZT. In this example, k₃₃ is 47% higher than kₜ.

Optionally an amount of uncut material is minimised, whilst attaining reliable machining.

Optionally the backing layer is graded and/or includes pores.

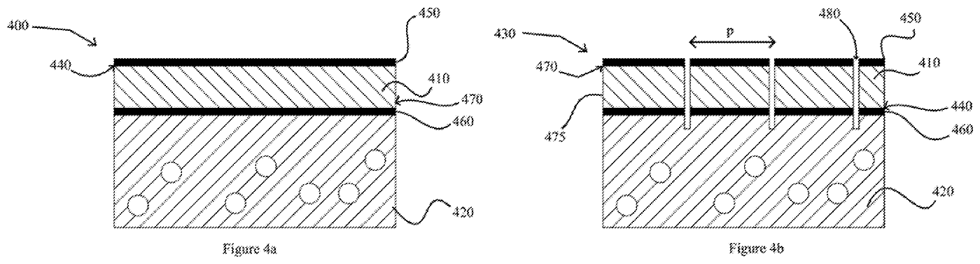

FIGS. 4a and 4b illustrate a third transducer array arrangement. FIG. 4a illustrates the third transducer array prior to a primary kerfing/cutting stage 400 in which primary kerfs/gaps/sits are provided through the piezoelectric layer 410 and into the backing layer 420. FIG. 4b illustrates the third array transducer following a primary kerfing/cutting stage 430. The array transducer illustrated in FIGS. 4a and 4b is manufactured as per the method illustrated in FIG. 1. The third transducer arrangement includes a piezoelectric layer 410 bonded to a backing layer 420 via a first face 440 of the piezoelectric layer. Two electrode layers 450, 460 are provided on the first face and a further face 470 of the piezoelectric layer 410. It will be understood that an electrode layer 460 is interspaced between the piezoelectric layer and backing layer. Optionally an electrode layer is provided on only one surface/face of the piezoelectric layer/region.

The third array transducer arrangement illustrated in FIG. 4 describes the manufacture of an array, and an array resulting from such manufacture, without pillars, or sub-elements. The array elements/piezoelectric elements 475 are cut to the desired array pitch by providing the primary kerfs 480 which extend through the piezoelectric layer, through the electrode layers, through the bonding layer and into the backing layer. The piezoelectric elements are therefore significantly wider and more robust and simpler to manufacture than sub-diced pillars utilised in other array transducer arrangements such as in the first and second array transducer arrangements described above and in FIGS. 2a to 3c. It will be appreciated that the third array transducer arrangement may provide enhanced reliability and increased volume of active/piezoelectric material, but potentially more cross talk and reliance on the thickness mode (kₜ) of the material. In the material available from the Applicant Ionix HPZ580, if used the difference in kₜ and k₃₃ is not so profound; k₃₃ is typically 10% higher than kₜ. This provides a significant advantage compared to conventional array transducer arrangements, array transducer arrangements including other piezoelectric materials and the first and second transducer arrangements described herein.

An Ionix HPZ580 piezoelectric layer included in the third array transducer arrangement has a higher performance than would be expected due to the above noted k₃₃/kₜ ratio.

In the third array transducer arrangement no sub-elements or pillars are used. The array is machined directly to the correct pitch.

Optionally the backing layer is graded and/or includes pores.

It will be appreciated that the first, second or third array transducer arrangements described above (and illustrated in FIGS. 2a-4b) may optionally include primary kerfs cut through the piezoelectric region/layer in a first direction only, thereby providing a 2D array. In such an array, portions of the piezoelectric material corresponding to the piezoelectric elements, or indeed sub-elements included within the piezoelectric elements, have an aspect ratio that is substantially plate-like or tile-like. It will be understood that the plate-like portions extend across the piezoelectric layer/region in a further direction that is perpendicular to the first direction along which the primary kerfs/slits are cut. It will also be understood that secondary kerfs may be provided in the piezoelectric layer along the first and/or further direction.

It will be appreciated that the first, second or third array transducer arrangements described above (and illustrated in FIGS. 2a-4b) may optionally include primary kerfs cut through the piezoelectric region/layer in both a first and further direction, thereby providing a 3D array. Optionally the first and further directions are substantially perpendicular. In such an array, portions of the piezoelectric material corresponding to the piezoelectric elements, or indeed sub-elements included within the piezoelectric elements, have an aspect ratio that is substantially bar-like or pillar-like. It will be understood that the plate-like portions extend perpendicularly to both the first and further directions. It will also be understood that secondary kerfs may be provided in the piezoelectric layer along the first and/or further direction.

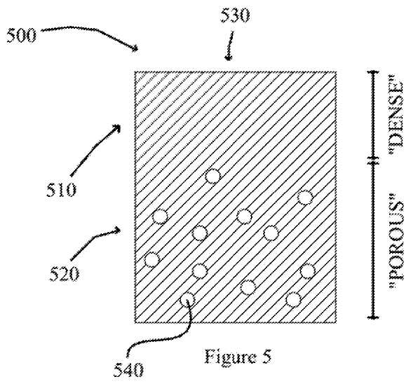

FIG. 5 illustrates a graded backing 500 for use in an array transducer arrangement. The graded backing of FIG. 5 may be utilised in any of the first, second or third array transducer arrangements illustrated in FIGS. 2a-4b. The graded backing 500 includes a relatively dense region 510 and a relatively porous region 520. It will be appreciated that the face 530 of the grading backing 500 proximate the dense region is arranged proximate to a piezoelectric layer in use in order to substantially match the acoustic impedance of the piezoelectric layer. A plurality of pores 540 are located in the porous region.

The acoustic impedance of the backing 500 is substantially matched to that of the piezoelectric materials used in a particular array transducer arrangement, and maintained through the temperature range. The backing may be formed from the same material as the piezoelectric layer, but contains internal porosity, and is unpoled. Optionally the porosity is <30 vol %, optionally being <20 vol %. Optionally the porosity is >5 vol %, optionally being >10% vol.

The backing 500 may be <10% porosity, <5% or essentially no porosity. The backing may optionally be a composite, a ceramic, a metal or a high temperature polymer.

The pores of the porous region of the backing layer are randomly arranged/scatted and form no set pattern. That is to say that the porosity is scattered and forms no set pattern. Optionally porosity may be highly ordered.

The porosity of the backing is graded. That is to say, the region of the backing material proximate to the active piezoelectric elements/layer has no, or lower, porosity than a region of the backing material which is further from the piezoelectric material/layer. In this manner, a strong bond and high acoustic energy transmission interface, is formed and the acoustic impedance is substantially well matched.

The face 530 of the backing proximate to the piezoelectric layer may is around <10% porosity. Optionally the porosity is <5%. Optionally the porosity <2% or zero porosity.

The porosity of the face 530 of the backing proximate to the piezoelectric layer has substantially the same level of porosity as the active piezoelectric elements. The thickness of the low porosity region is optionally <10 mm, or <5 mm. Optionally the thickness of the low porosity region is <3 mm, or <2 mm, or <1 mm. The thickness of this low porosity region is optionally >λ/4. Optionally the thickness is >0.1, 0.2, 0.3, 0.5, or 1.0 mm.

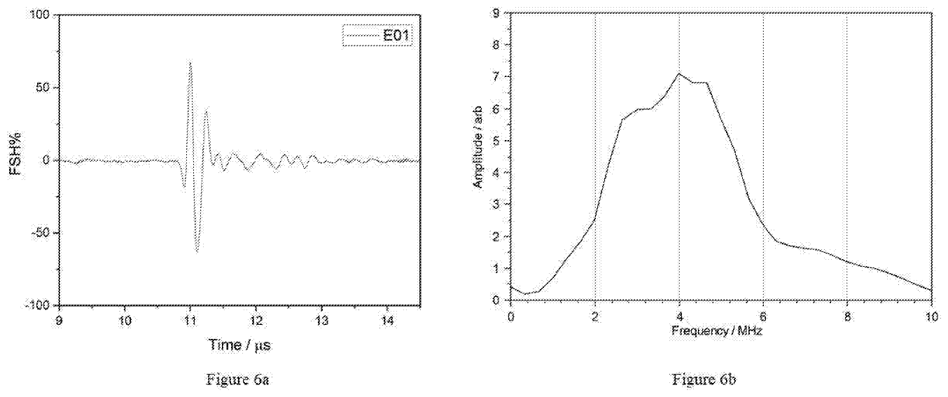

FIG. 6 illustrates measurements of a second array transducer (Relating to FIG. 3) arrangement element according to EN 12668-2. FIG. 6a illustrates an ultrasonic A-scan, an ultrasonic pulse reflection through a known thickness calibration block of carbon steel at 20° C. represented in time of flight (abscissas) and relative amplitude (ordinate). A Fast Fourier Transform of the reflection FIG. 6a is illustrated in FIG. 6b represented as frequency (abscissas) and amplitude (ordinate). Analysis according to EN 12668-2 presents a performance specification as shown in the table below.

| Parameter | Units | Value |
|---|---|---|
| Centre frequency | MHz | 4.00 |
| −6 dB bandwidth | % | 82 |

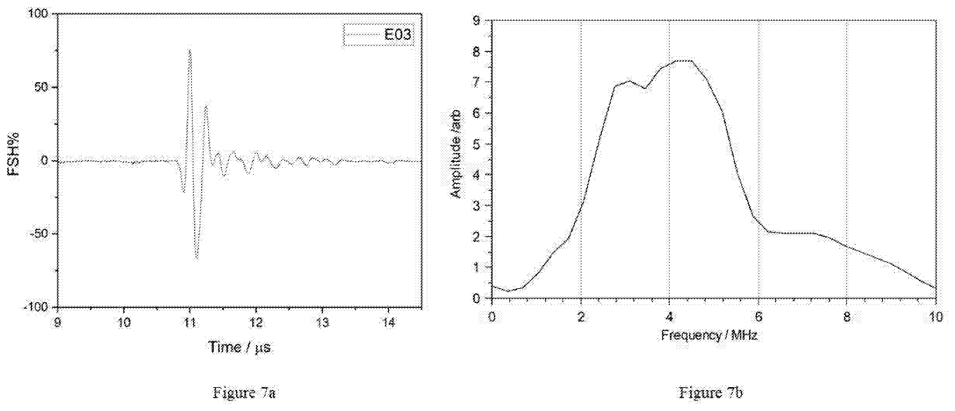

FIG. 7 illustrates measurements of a third array transducer arrangement (Relating to FIG. 4) element according to EN 12668-2. FIG. 7a illustrates an ultrasonic A-scan, an ultrasonic pulse reflection through a known thickness calibration block of carbon steel at 20° C. represented in time of flight (abscissas) and relative amplitude (ordinate). A Fast Fourier Transform of the reflection FIG. 7a is illustrated in FIG. 7b represented as frequency (abscissas) and amplitude (ordinate). Analysis according to EN 12668-2 presents a performance specification as shown in the table below.

| Parameter | Units | Value |
|---|---|---|
| Centre frequency | MHz | 4.30 |
| −6 dB bandwidth | % | 76 |

An increased bandwidth, or decreased pulse length, is observed in the second array transducer element assembled from sub-diced pillars when compared to the third array transducer element, in line with an increased k; recall that the second array utilizes predominantly the k₃₃ mode, whilst the third predominantly the kₜ mode, where kₜ<k₃₃. The increased damping also suppresses the centre frequency. It is understood that the array modes presented therefore are tailorable to the application.

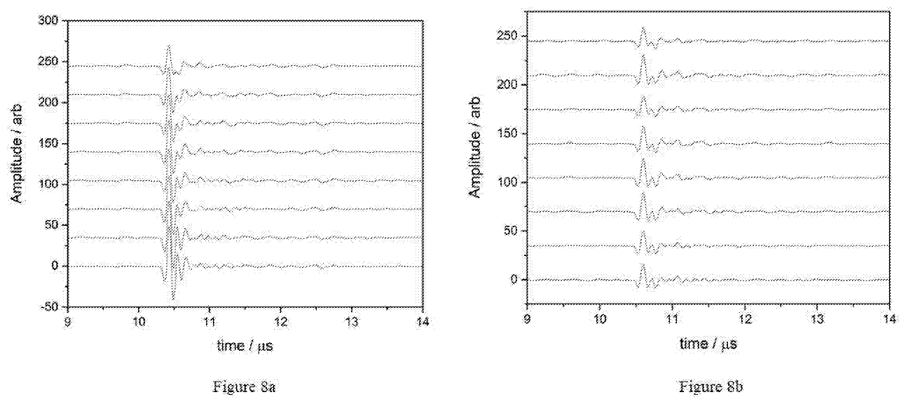

FIG. 8a illustrates a graph showing stacked A-scans of 8 elements of a 4 MHz array manufactured as per the third array transducer arrangement coupled with gel couplant to a carbon steel block 10 mm thick at 20° C., with each element individually excited with a 100 V, 80 ns pulse with 18 dB of gain on the receiver (measurements as per EN 12668-2).

FIG. 8b illustrates a graph showing stacked A-scans of 8 elements from a 4 MHz array manufactured as per the third array transducer arrangement coupled with high-temperature couplant to a carbon steel block 10 mm thick at 200° C., with each element individually excited with a 100 V, 80 ns pulse with 7 dB of gain on the receiver (measurements as per EN 12668-2).

A drop in gain from 18 to 7 dB with increasing temperature from 20 to 200° C. is observed for the array manufactured in accordance with the third array transducer arrangement. This constitutes an increase in voltage sensitivity of a factor of 3.5. The reason for this increase is due to a combination of:
The activity of piezo will increase with temperature, and provide an improvement in sensitivity.
The sound velocity in the test block decreases with temperature, closer matching the acoustic impedance form the transducer and steel.
The electrical impedance of the piezo may have changed, potentially matching better to either or the generator or input scope impedance.

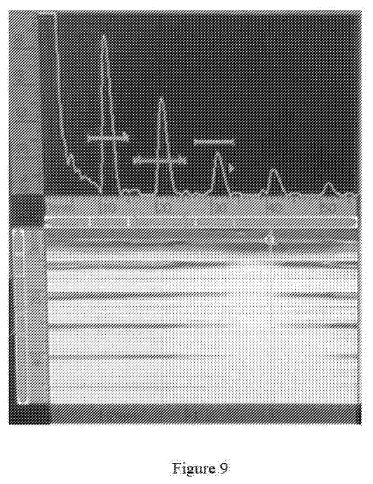

FIG. 9 illustrates a typical ultrasonic flaw detector display for a 16 element ultrasonic array. An a-scan (upper) of a single element, and b-scan (lower) of all 16 elements from an ultrasonic flaw detector for the third array transducer arrangement element, measured at 20° C. When the 16 elements are connected to a commercially available ultrasonic flaw detector, the array pulses may be phased such that an ultrasonic wavefront is generated at variable angles, or with a programmable aperture. Illustrated in FIG. 9 the B-scan clearly shows a shallow defect in the carbon steel test piece when tested for the application of ultrasonic wall thickness measurement. The elements are fired in groups of 2, with incremental steps of 1, to create an artificial aperture.

Optionally the piezoelectric layer and/or piezoelectric elements of the array transducer arrangement illustrated in FIGS. 2a and 2b, and/or FIGS. 3a, 3b and 3c, and/or FIGS. 4a and 4b is formed from the materials, and/or is manufactured according to the methods, described below.

Transducers and array transducers comprising piezoelectric elements may optionally be formed with BF-KBT-PT included in the piezoelectric region/layer and may be able to operate within, and/or above, a temperature range of 250° C. to 500° C. BF-KBT-PT piezoelectric elements may be able to withstand higher temperatures compared with piezoelectric elements made from PZT. The BF-KBT-PT piezoelectric elements may also be more sensitive and demonstrate increased activity and functional performance compared with piezoelectric elements made from other bismuth titanate materials. For example, BF-KBT-PT may offer up to 2-15 times the activity of other bismuth titanate materials when used in a transducer operating under the same conditions.

The piezoelectric activity may describe temperature dependent actuation of the piezoelectric material and may be related to the piezoelectric charge constant d₃₃, which may describe the mechanical strain experienced by a piezoelectric material per unit of electric field applied. Alternatively, it may refer to the polarization generated per unit of mechanical stress applied to a piezoelectric material.

A piezoelectric layer/region, piezoelectric element, or backing layer for an array transducer arrangement according to certain aspects of the present invention may optionally be fabricated utilising a method whereby a sinterable form of a mixed metal oxide containing Bi, K, Fe and Ti (and optionally Pb) is sintered at an appropriate temperature in order to produce the required piezoelectric material. An example of such a method is described below.

The ceramic is optionally obtainable by a process comprising the following steps: (A) preparing an intimate mixture of a substantially stoichiometric amount of a compound of each of Bi, K, Ti and Fe (and optionally Pb); (B) converting the intimate mixture into an intimate powder; (C) inducing a reaction in the intimate powder to produce a mixed metal oxide; (D) manipulating the mixed metal oxide into a sinterable form; and (E) sintering the sinterable form of the mixed metal oxide to produce the ceramic. Optionally, in step (A), one or more of the compounds of Fe, Ti, K and Bi (and optionally Pb) departs from a stoichiometric amount. For example, one or more of Fe, Ti, K and Bi (and optionally Pb) is optionally present in excess of the stoichiometric amount. For example, the atomic % may depart from stoichiometry by ±20% or less, or by ±10% or less or by ±5% or less. By departing from stoichiometry, the ceramic may be optionally equipped with oxide phases (e.g. perovskite phases).

In step (A) the substantially stoichiometric amount of the compound of each of Bi, K, Ti and Fe (and optionally Pb) may be expressed by the compositional formula: x(Bi_{b}K_{c})TiO₃-y(BiFe_{1-d}B_{d}O₃)-zPbTiO₃ wherein: B is a B-site metal dopant, such as optionally Ti, Mn, Co or Nb; b is optionally in the range 0.4 to 0.6; c is optionally in the range 0.4 to 0.6; d is optionally in the range 0 to 0.5; and x, y and z are optionally as hereinbefore defined.

The compound of each of Bi, K, Ti and Fe (and aptly Pb) may be independently selected from the group consisting of an oxide, nitrate, hydroxide, hydrogen carbonate, isopropoxide, polymer and carbonate, optionally an oxide and carbonate. Some non-limiting examples are Bi₂O₃ and K₂CO₃.

The intimate mixture may be slurry (e.g. milled slurry), a paste, a suspension, dispersion, a sol-gel or a molten flux. Step (C) may include heating (e.g. calcining). Optionally step (C) includes stepwise or interval heating. Step (C) may include stepwise or interval cooling. Where the intimate mixture is a slurry, the compound may be a salt (e.g. a nitrate). Where the intimate mixture is a sol-gel, the compound may be an isopropoxide.

Where the intimate mixture is a molten flux, the compound may be an oxide dissolved in a salt flux. The mixed metal oxide from step (C) may be precipitated out on cooling. Optionally the intimate powder is a milled powder. Step (A) may be: (A1) preparing a slurry of a substantially stoichiometric amount of a compound of each of Bi, K, Ti and K (and optionally Pb); (A2) milling the slurry; and step (B) may be (BI) drying the slurry to produce the milled powder.

Step (D) may include milling the mixed metal oxide. Step (D) may include pelletising the mixed metal oxide. Step (D) may include suspending the mixed metal oxide in an organic solvent.

Step (D) may include painting, spraying or printing the mixed metal oxide suspension to prepare for sintering.

Step (E) may be stepwise or interval sintering. Optionally step (E) includes stepwise or interval heating and stepwise or interval cooling. Step (E) may be carried out in the presence of a sintering aid. The presence of a sintering aid may promote densification. The sintering aid may be CuO₂.

Aptly, the ceramic further comprises a pre-sintering additive which is present in an amount of 75 wt % or less, optionally 50 wt % or less, or 25 wt % or less, or 5 wt % or less. The pre-sintering additive may be present in a trace amount.

The pre-sintering additive may be a perovskite or, alternatively, optionally a layered perovskite such as Bi₄Ti₃O₁₂. The pre-sintering additive may also be a lead-containing perovskite such as PbTiO₃ or PbZrO₃. The pre-sintering additive may be added post-reaction (e.g. post-calcination) in order to form the mixed metal oxide containing Bi, K, Fe and Ti (and optionally Pb). In this way, the pre-sintering additive may act as a sintering aid to fabrication process.

The transducer may be configured to be operable as at least one of a contact transducer, a single element transducer, a dual element transducer, as an angle beam transducer, a delay line transducer, a flexural mode transducer, and an immersion transducer. The transducer may also be configured to be operable as a 1 dimensional or 2 dimensional array suitable for use as a composite single element transducer, a full matrix capture sensor, or as a phased array.

The glass bonding layer of any of the above described transducer arrangements may be configured such that it can be cured at a temperature below 600° C., or optionally below 580° C., which may remove a need to re-polarize the piezoelectric element. Alternatively, configuring the bonding layer so that it is cured at a temperature below 450° C. may enable the transducer to be bonded, in air, to a substrate comprising 400 series steel without causing significant corrosion to the substrate. Furthermore, configuring the bonding layer such that it may be cured at 350° C. or more, may enable the transducer to be used for monitoring the components of a nuclear power plant, including the monitoring of low pressure steam, for example. A curing temperature of the bonding layer between 350° C. and 400° C. may enable the transducer to be used for monitoring the components of chemical processing plant. Alternatively, configuring the bonding layer such that it can be cured within a range of temperatures between 550° C. and 565° C. may enable the transducer to be used for the permanent monitoring of conditions within a conventional gas or coal fired power station.

All of the features disclosed in this specification (including any accompanying claims, abstract and drawings), and/or all of the steps of any method or process so disclosed, may be combined in any combination, except combinations where at least some of such features and/or steps are mutually exclusive.

Each feature disclosed in this specification (including any accompanying claims, abstract and drawings) may be replaced by alternative features serving the same, equivalent or similar purpose, unless expressly stated otherwise. Thus, unless expressly stated otherwise, each feature disclosed is one example only of a generic series of equivalent or similar features.

The invention is not restricted to the details of the foregoing embodiment(s). The invention extends to any novel one, or any novel combination, of the features disclosed in this specification (including any accompanying claims, abstract and drawings), or to any novel one, or any novel combination, of the steps of any method or process so disclosed.

1-69. (canceled)

70. A backing layer for an array transducer arrangement, comprising:
a relatively dense first region; and
a which is relatively porous further region; wherein
the further region comprises pores to scatter/absorb sound.

71. The backing layer as claimed in claim 70, further comprising:
Ionix HPZ-580.

72. An array transducer arrangement for use in a high temperature environment, comprising:
at least one piezoelectric layer;
at least one electrode layer; and
at least one backing layer; wherein
the at least one backing layer includes a first region proximate to the piezoelectric layer and a further region distal to the piezoelectric layer, the further region including a plurality of pores.

73. The array transducer arrangement as claimed in claim 72, wherein:
the further region is porous.

74. The array transducer arrangement as claimed in claim 72, wherein:
the first region has an acoustic impedance being substantially similar to the acoustic impedance of the piezoelectric layer.

75. The array transducer arrangement as claimed in claim 72, wherein:
the piezoelectric layer comprises a region of Ionix HPZ-580 material.

76. The array transducer arrangement as claimed in claim 72 wherein:
the backing layer comprises a region of Ionix HPZ-580 material.

77. The array transducer arrangement as claimed in claim 72, further comprising:
a plurality of primary kerfs though the piezoelectric layer, through the electrode layer, through and into the backing layer to define a plurality of piezoelectric elements of a particular pitch.

78. The array transducer arrangement as claimed in claim 72, further comprising:
a plurality of secondary kerfs into the piezoelectric layer, the secondary kerfs extending partially through the piezoelectric layer to provide a plurality of sub-elements.

79-86. (canceled)

87. The backing layer as claimed in claim 70, further comprising:
Ionix HPZ-580 in a depoled state.

88. The array transducer arrangement as claimed in claim 76, wherein the backing layer comprises a region of Ionix HPZ-580 material in a depoled state.
